(19) United States
(12) Patent Application Publication
(10) Pub. No.: US 2026/0302038 A1
(43) Pub. Date: Oct. 1, 2026

(54) COIL DEVICE AND IN-VEHICLE DEVICE

(71) Applicant: Mitsubishi Electric Corporation, Chiyoda-ku, Tokyo (JP)

(72) Inventor: Shinichi YAMASAKI, Chiyoda-ku, Tokyo (JP)

(73) Assignee: Mitsubishi Electric Corporation, Chiyoda-ku, Tokyo (JP)

(21) Appl. No.: 19/478,974

(22) PCT Filed: Aug. 4, 2023
(86) PCT No.: PCT/JP2023/028624

§ 371 Date: Oct. 27, 2025

(51) Int. Cl. H01F 27/08; B61C 3/00; H01F 27/02; H01F 27/28

(52) U.S. Cl. CPC H01F 27/08; B61C 3/00; H01F 27/025; H01F 27/28

(57) ABSTRACT

A coil device includes a coil wound around its central axis, and a casing having a cavity therein to accommodate the coil in the cavity and being made of a casted or injection molded product. The casing is accommodated in a duct such that at least a part of a bottom surface of the casing abuts on a first wall surface being an inner surface of the duct located below in the vertical direction. The duct extends in a direction intersecting the vertical direction inside a housing of an in-vehicle device, and defines a space into which the air outside the housing flows. The casing is fixed to the first wall surface and a second wall surface being an inner surface of the duct located above in the vertical direction.

### TECHNICAL FIELD

The present disclosure relates to a coil device and an in-vehicle device including the coil device.

### BACKGROUND ART

Some in-vehicle devices include coil devices, such as reactors and transformers. Such in-vehicle devices also include structures for discharging heat generated in the coil devices in order to prevent the coil devices from being damaged by the heat during energization. This type of in-vehicle device is disclosed in Patent Literature 1, for example. Patent Literature 1 discloses an electric motor including an inverter circuit having a choke coil. This choke coil is disposed on the bottom of a structural member suspended from a motor housing. The structural member and the motor housing transfer heat generated in the choke coil to the exterior of the electric motor.

### CITATION LIST

### Patent Literature

Patent Literature 1: Unexamined Japanese Patent Application Publication No. 2018-026508

### SUMMARY OF INVENTION

### Technical Problem

A typical in-vehicle device of a railway vehicle includes a large-capacity reactor, because the main circuit of the in-vehicle device receives a higher current than that in an in-vehicle device of an automobile. That is, the in-vehicle device of the railway vehicle includes a coil device having greater size and weight than the coil device included in the in-vehicle device of the automobile. Installation of the electric motor disclosed in Patent Literature 1 in a railway vehicle needs a larger thickness of the portion of the motor housing from which the structural member is suspended, and needs more secure fixation of the structural member to the motor housing. These needs inevitably increase the overall size of the electric motor. Such an increase in size can be problematic not only in motor devices but also other in-vehicle devices including coil devices.

An objective of the present disclosure, which has been accomplished in view of the above situations, is to provide a coil device that can reduce the size of an in-vehicle device including the coil device, and a compact in-vehicle device.

### Solution to Problem

In order to achieve the above objective, a coil device according to the present disclosure includes a coil and a casing. The coil is wound around the central axis thereof. The casing has a cavity therein to accommodate the coil in the cavity, and is made of a casted or injection molded product. The casing is accommodated in a duct such that at least a part of a bottom surface of the casing abuts on a first wall surface being an inner surface of the duct located below in the vertical direction. The duct extends in a direction intersecting the vertical direction inside a housing of an in-vehicle device, and defines a space into which the air outside the housing flows. The casing is fixed to the first wall surface and a second wall surface being an inner surface of the duct located above in the vertical direction.

### Advantageous Effects of Invention

In the coil device according to the present disclosure, the casing made of a casted or injection molded product for accommodating the coil is fixed to the first wall surface being the inner surface of the duct located below in the vertical direction, such that at least a part of the bottom surface of the casing abuts on the first wall surface. The casing is also fixed to the second wall surface being the inner surface of the duct located above in the vertical direction. This coil device does not need a member for supporting the coil, like a structural member suspended from a housing to support a coil. The coil device can thus reduce the size of the in-vehicle device including the coil device.

### BRIEF DESCRIPTION OF DRAWINGS

FIG. 1 is a perspective view of an in-vehicle device according to Embodiment 1;

FIG. 2 is a sectional view of the in-vehicle device according to Embodiment 1 taken along the line II-II of FIG. 1;

FIG. 3 is a sectional view of the in-vehicle device according to Embodiment 1 taken along the line III-III of FIG. 2;

FIG. 4 is a perspective view of a coil device according to Embodiment 1;

FIG. 5 is a sectional view of an in-vehicle device according to Embodiment 2;

FIG. 6 is a sectional view of the in-vehicle device according to Embodiment 2 taken along the line VI-VI of FIG. 5;

FIG. 7 is a sectional view of the in-vehicle device according to Embodiment 2;

FIG. 8 is a perspective view of a modification of the coil device according to the embodiments; and

FIG. 9 is a sectional view of a modification of the in-vehicle device according to the embodiments.

### DESCRIPTION OF EMBODIMENTS

A coil device and an in-vehicle device according to some embodiments of the present disclosure are described in detail below with reference to the accompanying drawings. In the drawings, the components identical or corresponding to each other are provided with the same reference symbol.

### Embodiment 1

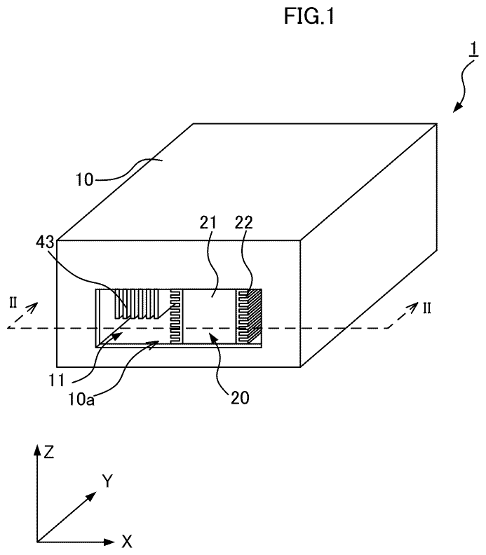

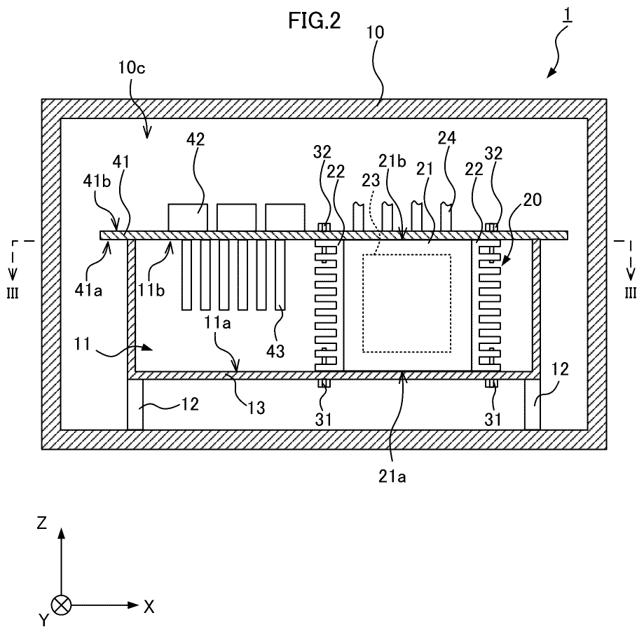

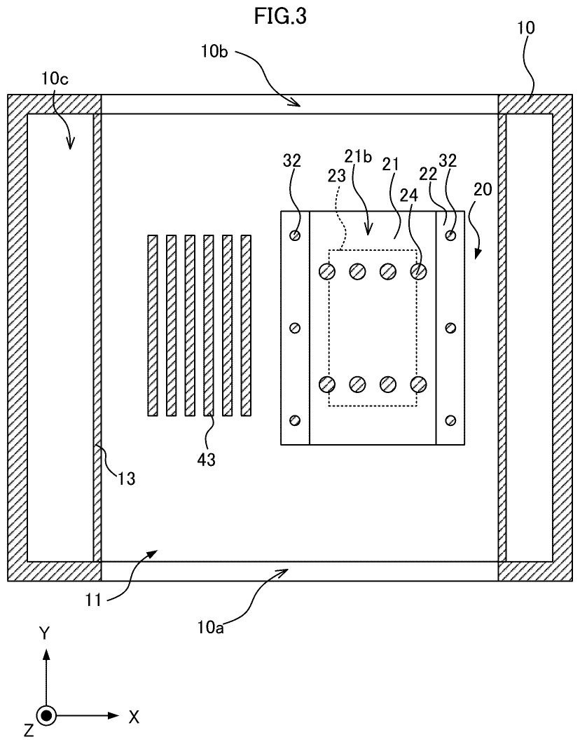

The description of Embodiment 1 focuses on an in-vehicle device 1, on the basis of an exemplary in-vehicle device to be installed in a railway vehicle. As illustrated in FIG. 1, FIG. 2, which is a sectional view taken along the line II-II of FIG. 1, and FIG. 3, which is a sectional view taken along the line III-III of FIG. 2, the in-vehicle device 1 is installed in a railway vehicle, and includes a housing 10 including a duct 11 therein. The in-vehicle device 1 includes a coil device 20 accommodated in the duct 11, first fasteners 31 and second fasteners 32 that fix the coil device 20 to the duct 11, and a heat-receiving block 41 that forms a part of the duct 11.

The heat-receiving block 41 has a first main surface 41a that faces toward the interior of the duct 11, and a second main surface 41b located opposite to the first main surface 41a. The in-vehicle device 1 in Embodiment 1 includes electronic components 42 mounted on the second main surface 41b, and heat radiating members 43 accommodated in the duct 11. In FIGS. 1 to 3, the Z axis represents the vertical direction when the railway vehicle is placed horizontally. The X axis represents the traveling direction of the railway vehicle, and the Y axis represents the width direction of the railway vehicle. The X, Y, and Z axes are orthogonal to each other.

The in-vehicle device 1 is, for example, a power conversion apparatus that converts electric power fed from an overhead line into three-phase AC power to be fed to a motor that generates propulsion force for the railway vehicle, and feeds the three-phase AC power to a main motor. The in-vehicle device 1 serving as the power conversion apparatus includes the coil device 20 that functions as a reactor generating heat during energization, for example. The coil device 20 is accommodated in the duct 11. The heat generated in the coil device 20 is discharged to the air that has entered the duct 11 from the exterior of the housing 10, resulting in cooling of the coil device 20. The coil device 20 includes a casing 21 fixed to the duct 11, and thus does not need an additional member for supporting the coil device 20, thereby reducing the size of the in-vehicle device 1.

The following describes individual components of the in-vehicle device 1 in detail.

The housing 10 is attached under the floor of the railway vehicle with fitting members, which are not illustrated. The housing 10 has two surfaces that face each other in the Y-axis direction and respectively have air holes 10a and 10b that interconnect with the duct 11. The air holes 10a and 10b are located at positions opposed to each other in the Y-axis direction.

The duct 11 extends in a direction intersecting the vertical direction inside the housing 10 and defines a space into which the air outside the housing 10 flows. The duct 11 in Embodiment 1 extends in the horizontal direction when the railway vehicle including the in-vehicle device 1 is placed horizontally. The duct 11 accommodates the coil device 20 and the heat radiating members 43. The duct 11 is supported by support members 12 mounted on the inner surface of the housing 10.

The duct 11 in Embodiment 1 is made of a lower duct segment 13 having a portion orthogonal to the Z axis and a portion orthogonal to the X axis, and a part of the heat-receiving block 41.

The lower duct segment 13 of the duct 11 supports the coil device 20 accommodated in the duct 11 in the vertical direction. The duct 11 has sufficient strength to remain undeformed despite vibrations generated during running of the railway vehicle. In detail, the lower duct segment 13 is preferably a casted or injection molded product made of a material capable of achieving sufficient strength, for example, a metal, such as aluminum, iron, or stainless-steel. Specifically, the lower duct segment 13 is preferably a casted or injection molded product having a thickness of at least 10 mm at any site.

The in-vehicle device 1 needs to have sufficient air tightness to suppress flow of the air outside the housing 10 into a space 10c. The space 10c is surrounded by the outer surface of the duct 11 and the inner surface of the housing 10 and accommodates the electronic components 42. The lower duct segment 13 and the heat-receiving block 41 thus preferably have smooth and flat end faces in the Y-axis direction that are in surface contact with the housing 10. The end faces of the lower duct segment 13 and the heat-receiving block 41 on the positive side in the Y-axis direction are preferably smoothly connected to each other. The end faces of the lower duct segment 13 and the heat-receiving block 41 on the negative side in the Y-axis direction are preferably smoothly connected to each other. The term “smoothly connected” indicates that the inclinations of the tangent planes transition continuously.

In Embodiment 1, the end faces of the lower duct segment 13 and the heat-receiving block 41 on the positive side in the Y-axis direction are located on the same plane, and the end faces of the lower duct segment 13 and the heat-receiving block 41 on the negative side in the Y-axis direction are located on the same plane.

To improve the air tightness of the in-vehicle device 1, the in-vehicle device 1 preferably includes a sealing member filled between the housing 10 and the end faces of the lower duct segment 13 and the heat-receiving block 41 in the Y-axis direction. A typical example of this sealing member is a resin having waterproofness and dustproofness.

The coil device 20 illustrated in FIGS. 1 to 4 includes the casing 21 made of a casted or injection molded product having a cavity therein, multiple fins 22 attached to a side surface of the casing 21 and accommodated in the duct 11, a coil 23 accommodated in the cavity in the casing 21, and conductors 24 having one ends connected to the coil 23 and extend to the exterior of the casing 21.

The casing 21 in Embodiment 1 includes a box having an opening at the upper end in the vertical direction, and a lid capable of opening and closing the opening of the box at the upper end in the vertical direction. The casing 21, made of a casted or injection molded product, has smaller dimensional tolerances compared to processed products fabricated by bending metal plates, like the duct 11. This feature allows a bottom surface 21a of the casing 21 to abut on a first wall surface 11a being an inner surface of the duct 11 located below in the vertical direction, and allows a top surface 21b of the casing 21 to abut on a second wall surface 11b being an inner surface of the duct 11 located above in the vertical direction, as illustrated in FIG. 2. The casing 21 thus causes the coil device 20 including the casing 21 to be fixed to and supported by the duct 11.

The casing 21 abutting on the first wall surface 11a and the second wall surface 11b of the duct 11 enables the coil device 20 to function as a structural member for maintaining the interior space of the duct 11. The casing 21 thus preferably has sufficient strength to remain undeformed despite vibrations generated during running of the railway vehicle. The casing 21 is preferably made of an aluminum plate having a thickness of at least 10 mm, for example.

The fins 22 are provided to the side surfaces of the casing 21, specifically, the surfaces of the casing 21 that intersect the X axis. The fins 22 are preferably flat plate members. The main surfaces of the fins 22 extend along the direction of extension of the duct 11. The fins 22 in Embodiment 1 are provided to the casing 21, such that the main surfaces of the fins 22 extend along a direction parallel to the XY plane. The fins 22 extend along the direction of extension of the duct 11, that is, the airflow direction inside the duct 11. This structure enables efficient transfer of heat generated in the coil 23 from the fins 22 to the air inside the duct 11. This heat transfer results in cooling of the coil 23.

The fins 22 are preferably made of a material having high thermal conductivity, for example, a metal, such as copper or aluminum. The fins 22 are fixed to the side surfaces of the casing 21 by any procedure, such as fitting, brazing, welding, adhesion with adhesives, or fastening with fasteners. Specifically, the fins 22 are fixed to the casing 21 with sufficient strength to maintain the positional relationship between the fins 22 and the casing 21 despite vibrations generated during running of the railway vehicle.

In Embodiment 1, the lowermost fins 22 in the vertical direction are fixed to the first wall surface 11a with the first fasteners 31 while being in surface contact with the first wall surface 11a. The uppermost fins 22 in the vertical direction are fixed to the second wall surface 11b with the second fasteners 32 while being in surface contact with the second wall surface 11b. This surface contact between the lowermost fins 22 in the vertical direction and the first wall surface 11a and between the uppermost fins 22 in the vertical direction and the second wall surface 11b enables efficient transfer of heat generated in the coil 23 from the fins 22 to the duct 11. This efficient heat transfer can increase the cooling capacity for the coil device 20 in the in-vehicle device 1.

The coil 23 is accommodated in the casing 21 in any orientation. The coil 23 is preferably accommodated in the casing 21 with its central axis aligned parallel to the Z or Y axis. The coil 23 is accommodated in the box of the casing 21, and the casing 21 is accommodated in the duct 11 while the opening of the box is closed by the lid of the casing 21. This structure suppresses exposure of the coil 23 to the air outside the housing 10 containing contaminants, such as dust and water vapor.

The conductors 24 have one ends disposed inside the casing 21 and connected to the coil 23. The conductors 24 extend via through holes formed in the lid of the casing 21 and the heat-receiving block 41 to the space inside the housing 10 and outside the duct 11. The conductors 24 have the other ends connected to electronic devices, which are not illustrated, inside the housing 10.

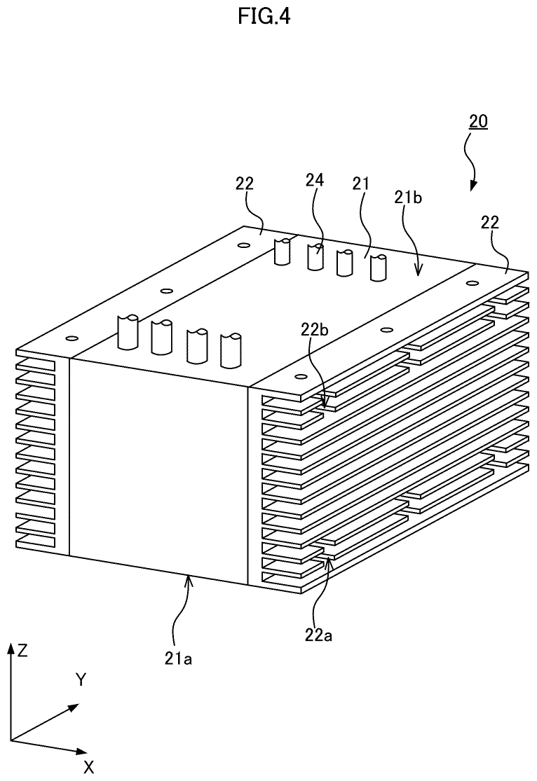

The first fasteners 31 include bolts to extend through the lower duct segment 13 and the lowermost fins 22 in the vertical direction, and nuts to fasten the bolts. The bolts extend through the lowermost fins 22 in the vertical direction, and are located in voids 22a between the fins 22 illustrated in FIG. 4.

The second fasteners 32 include bolts to extend through the heat-receiving block 41 that defines the duct 11 and the uppermost fins 22 in the vertical direction, and nuts to fasten the bolts. The bolts extend through the uppermost fins 22 in the vertical direction, and are located in voids 22b between the fins 22 illustrated in FIG. 4.

The heat-receiving block 41 has the first main surface 41a, and the second main surface 41b located opposite to the first main surface 41a. The heat-receiving block 41 is preferably a flat plate member. The first main surface 41a and the second main surface 41b in Embodiment 1 are located opposite to each other in the Z-axis direction. The heat-receiving block 41 defines the duct 11. In detail, a portion of the first main surface 41a of the heat-receiving block 41 corresponds to the second wall surface 11b of the duct 11. The first main surface 41a that faces toward the interior of the duct 11 is provided with the heat radiating members 43. The second main surface 41b located opposite to the first main surface 41a of the heat-receiving block 41 is provided with the electronic components 42 serving as heating elements.

The heat-receiving block 41 is mounted on the upper end of the lower duct segment 13 in the vertical direction, and forms the duct 11 along with the lower duct segment 13. The heat-receiving block 41 is preferably attached to the lower duct segment 13 with sufficient strength to maintain the positional relationship between the heat-receiving block 41 and the lower duct segment 13 despite vibrations generated during running of the railway vehicle, by any procedure, such as fitting, brazing, welding, adhesion with adhesives, or fastening with fasteners.

The heat-receiving block 41, forming a part of the duct 11, preferably has sufficient strength to remain undeformed despite vibrations generated during running of the railway vehicle, like the duct 11. The heat-receiving block 41 preferably has sufficient thermal conductivity to transfer heat generated in the electronic components 42 to the heat radiating members 43. The heat-receiving block 41 is preferably made of a material having sufficient strength and high thermal conductivity, for example, aluminum. Specifically, the heat-receiving block 41 is preferably made of an aluminum plate having a thickness of at least 10 mm.

The electronic components 42 are switching elements included in a power conversion circuit, for example, and generate heat during energization. The electronic components 42 are provided to the second main surface 41b located opposite to the first main surface 41a forming the second wall surface 11b of the duct 11. This structure suppresses exposure of the electronic components 42 to the air outside the housing 10 that has entered the duct 11.

The heat radiating members 43 are provided to the first main surface 41a of the heat-receiving block 41. The heat radiating members 43 in Embodiment 1 are aligned in the X-axis direction, such that the heat radiating members 43 adjacent to each other have an interval therebetween. The heat radiating members 43 discharge heat transferred from the electronic components 42 via the heat-receiving block 41, to the air flowing through the intervals. The heat radiating members 43 in Embodiment 1 each have a fin shape. The main surfaces of the heat radiating members 43 extend along the direction of extension of the duct 11. The heat radiating members 43 in Embodiment 1 are provided to the heat-receiving block 41 such that their main surfaces extend in parallel to the YZ plane. The heat radiating members 43 extend along the direction of extension of the duct 11, that is, the airflow direction inside the duct 11, and thus efficiently transfer heat generated in the electronic components 42 from the heat radiating members 43 to the air inside the duct 11. This heat transfer results in cooling of the electronic components 42.

The heat radiating members 43 are preferably made of a material having high thermal conductivity, for example, a metal, such as copper or aluminum. The heat radiating members 43 are fixed to the first main surface 41a of the heat-receiving block 41 by any procedure, such as fitting, brazing, welding, adhesion with adhesives, or fastening with fasteners. Specifically, the heat radiating members 43 are fixed to the heat-receiving block 41 with sufficient strength to maintain the positional relationship between the heat radiating members 43 and the heat-receiving block 41 despite vibrations generated during running of the railway vehicle.

The heat radiating members 43 discharge heat transferred from the electronic components 42 via the heat-receiving block 41, to the air that has entered the duct 11. This heat discharge results in cooling of the electronic components 42. In Embodiment 1, the heat radiating members 43 each have a fin shape, and the main surfaces of the heat radiating members 43 extend along the direction of extension of the duct 11. In detail, the heat radiating members 43 are provided to the heat-receiving block 41, such that the main surfaces of the heat radiating members 43 extend in parallel to the YZ plane.

In the in-vehicle device 1 having the above-described configuration, the air that has entered the duct 11 through the air hole 10a flows between the fins 22 or between the heat radiating members 43 and exits through the air hole 10b to the exterior of the housing 10, for example. The air flowing between the fins 22 receives heat generated in the coil 23, and thus cools the coil 23. The air flowing between the heat radiating members 43 receives heat generated in the electronic components 42, and thus cools the electronic components 42.

As described above, the coil device 20 according to Embodiment 1 includes the casing 21 made of a casted or injection molded product having small dimensional tolerances. The coil device 20 thus does not need a clearance around the casing 21 inside the duct 11, and allows the casing 21 to be accommodated in the duct 11 while maintaining the casing 21 in contact with the first wall surface 11a and the second wall surface 11b of the duct 11.

The coil device 20 does not need an additional member for supporting the coil device 20, because of the duct 11 that supports the coil device 20 including the casing 21 abutting on the first wall surface 11a. The coil device 20 thus reduces the size of the in-vehicle device 1 compared to that of an in-vehicle device including a member for supporting a coil device.

The casing 21, abutting on the first wall surface 11a and the second wall surface 11b of the duct 11, and the coil 23 accommodated in the casing 21 are less susceptible to vibrations generated during running of the railway vehicle.

The casing 21, abutting on the first wall surface 11a and the second wall surface 11b of the duct 11, functions as a structural member for maintaining the interior space of the duct 11. This casing 21 does not need an additional reinforcement member for maintaining the interior space of the duct 11, and reduces the size of the duct 11 in the in-vehicle device 1 compared to that of a power conversion apparatus including a reinforcement member for maintaining the interior space of a duct.

The surface contact between the lowermost fins 22 in the vertical direction and the first wall surface 11a and between the uppermost fins 22 in the vertical direction and the second wall surface 11b enables efficient transfer of heat generated in the coil 23 from the fins 22 to the duct 11. This efficient heat transfer increases the cooling capacity for the coil device 20 in the in-vehicle device 1.

### Embodiment 2

The coil device 20 may be disposed in a manner other than that in the above-described example. The description of Embodiment 2 focuses on a power conversion apparatus in which the coil device 20 is disposed in a manner different from that in Embodiment 1, on the basis of the differences from Embodiment 1.

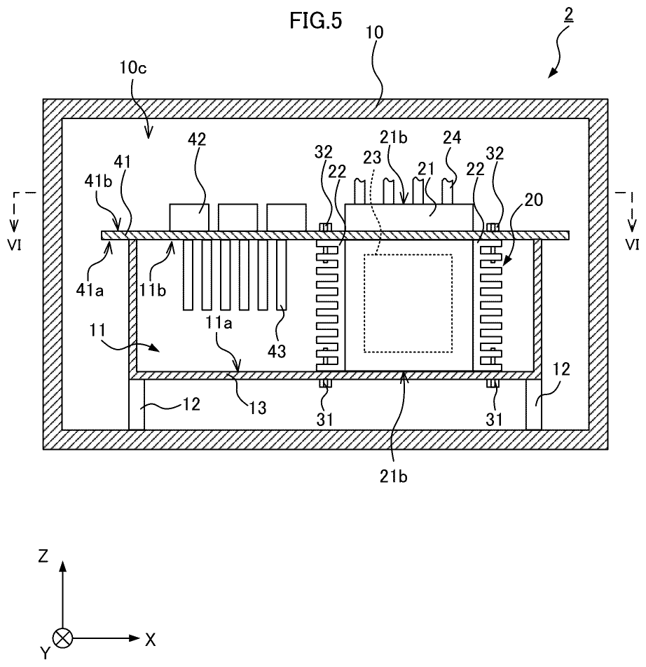

FIG. 5 illustrates an in-vehicle device 2 according to Embodiment 2 including the same components as the in-vehicle device 1 according to Embodiment 1. In the in-vehicle device 2, the coil device 20 partially protrudes into the space 10c corresponding to the exterior of the duct 11.

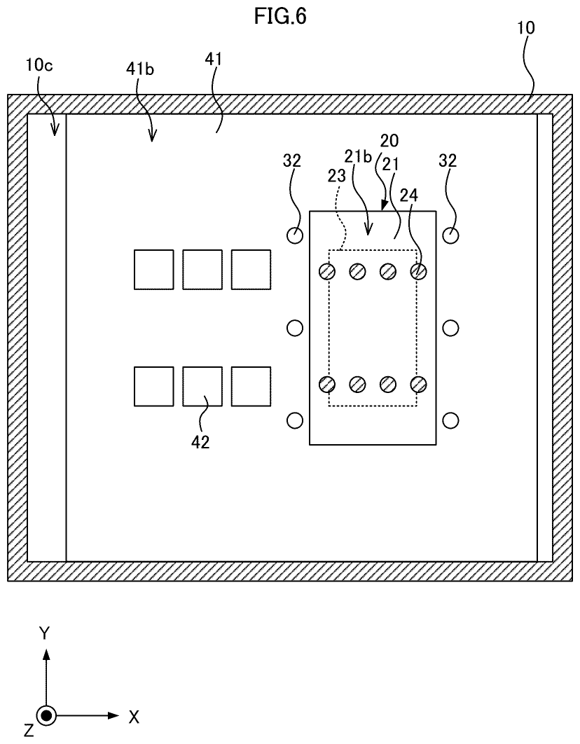

As illustrated in FIG. 5, and FIG. 6, which is a sectional view taken along the line VI-VI of FIG. 5, the upper end of the casing 21 in the vertical direction is located above the heat-receiving block 41 in the vertical direction.

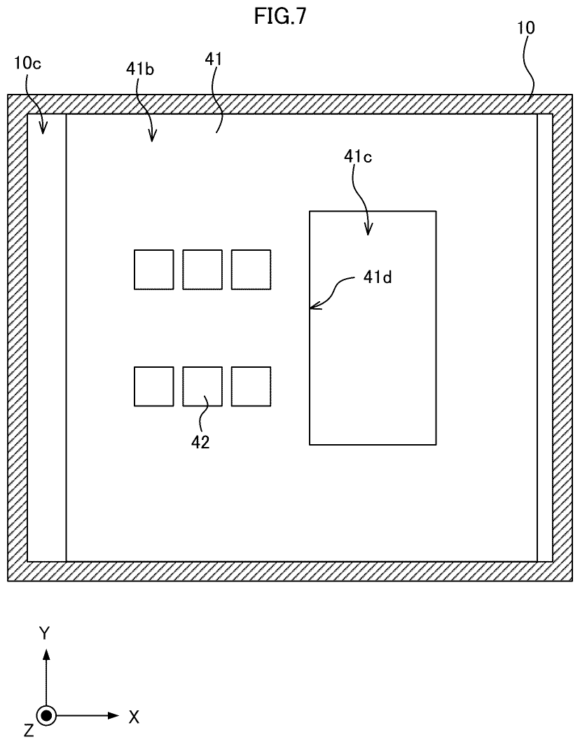

As illustrated in FIG. 7, depicted by excluding the coil device 20 from FIG. 6, the heat-receiving block 41 has an interconnecting hole 41c. The casing 21 protruding through the interconnecting hole 41c into the space 10c is preferably fixed to the duct 11 while abutting on a hole wall surface 41d that is the inner wall of the interconnecting hole 41c. The hole wall surface 41d is preferably covered with a resin having waterproofness and dustproofness, for example, in order to prevent the air inside the duct 11 from entering the space 10c.

As described above, the coil device 20 included in the in-vehicle device 2 according to Embodiment 2 is fixed to the duct 11 while partially protruding into the exterior of the duct 11. This structure enables the size of coil device 20 to be determined independently of the duct 11, thus enhancing the degree of design flexibility for the coil device 20.

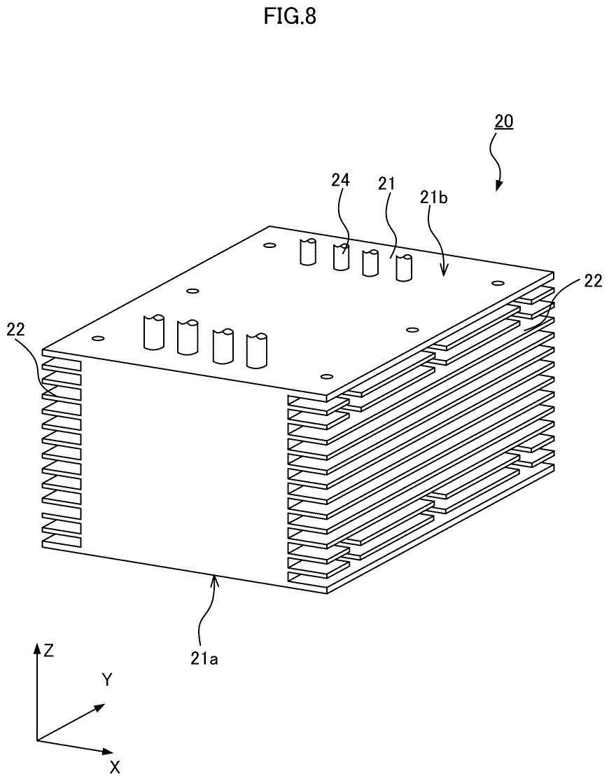

The present disclosure is not limited to the above-described embodiments. The definition of “fixation” in the above-described embodiments also encompasses integral formation. For example, the casing 21 and the fins 22 may be integrally formed, as illustrated in FIG. 8. The integrally formed casing 21 and fins 22 enable more efficient heat transfer from the coil 23 accommodated in the casing 21 via the casing 21 to the fins 22.

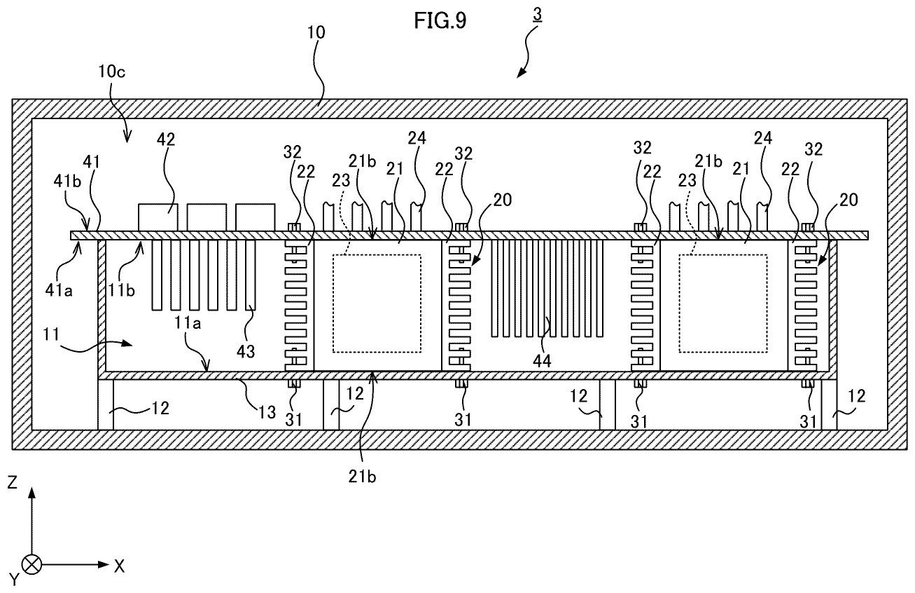

The in-vehicle device may include any number of coil devices. For example, an in-vehicle device 3 illustrated in FIG. 9 includes two coil devices 20 accommodated in the same duct 11, and heat radiating members 43 and 44. Each of the coil devices 20 has the configuration similar to the coil device 20 included in the in-vehicle device 1 according to Embodiment 1. The heat radiating members 44 have a vertical length longer than the vertical length of the heat radiating members 43. Alternatively, the in-vehicle device 3 may include multiple coil devices 20 each partially protruding into the exterior of the duct 11 as in Embodiment 2.

The heat radiating members 43 and 44 may have any shape capable of transferring heat to the air that has entered the duct 11, other than the shapes in the above-described embodiments. For example, the heat radiating members 43 and 44 may each be a protrusion extending in a direction away from the first main surface 41a forming the second wall surface 11b. In this modification, the heat radiating members 43 and 44 preferably have distal ends thinner than the proximal ends fixed to the first main surface 41a.

The heat radiating members 43 and 44 may also be heat pipes. In this modification, the heat radiating members 43 and 44 preferably have headers embedded in the heat-receiving block 41 and extending in the airflow direction inside the duct 11, and branch pipes interconnecting with the headers and extending in directions away from the heat-receiving block 41. The heat radiating members 43 and 44 may also include fins fixed to the branch pipes.

To prevent the air outside the housing 10 from entering the space 10c from the duct 11, the sites of contact between the upper end of the lower duct segment 13 in the vertical direction and the heat-receiving block 41 preferably undergo waterproof and dustproof treatment. A typical example of the waterproof and dustproof treatment is application of a resin having waterproofness and dustproofness.

The in-vehicle devices 1, 2, and 3 may each be any device installed in a vehicle and including a heating element, other than the power conversion apparatus that converts electric power fed from the overhead line into three-phase AC power to be fed to a main motor. The in-vehicle devices 1, 2, and 3 may be installed in any moving body, such as automobile, aircraft, or vessel, other than the railway vehicle.

The housing 10 may also be mounted on the roof of the railway vehicle.

The housing 10 may be mounted in an orientation other than that in the above-described examples. For example, the in-vehicle devices 1 to 3 may each be installed in the railway vehicle such that the duct 11 extends in the direction orthogonal to the X-axis direction.

The duct 11 may have any structure other than that in the above-described examples, provided that the duct 11 can introduce air into the housing 10 and accommodate the coil device 20. For example, the duct 11 may be attached directly to the bottom surface of the housing 10. For another example, the inner surface of the housing 10 may form he first wall surface 11a.

The fins 22 may have any arrangement and shape other than those in the above-described examples, provided that the fins 22 can discharge heat transferred from the coil device 20 to the air inside the duct 11. For example, the fins 22 may be provided to the surfaces of the casing 21 orthogonal to the Y-axis direction. For another example, the lowermost fins 22 in the vertical direction may be located apart from the first wall surface 11a of the duct 11. In this modification, the bottom surface 21a of the casing 21 is preferably in surface contact with the first wall surface 11a and fixed to the first wall surface 11a. Also, the uppermost fins 22 in the vertical direction may be located apart from the second wall surface 11b of the duct 11. In this modification, the top surface 21b of the casing 21 is preferably in surface contact with the second wall surface 11b.

The in-vehicle devices 1 to 3 may each include a fan for forcibly delivering air to the duct 11. This fan may be disposed outside the duct 11 to deliver air to the duct 11, or may be disposed inside the duct 11 to guide the air outside the housing 10 into the interior of the duct 11.

The foregoing describes some example embodiments for explanatory purposes. Although the foregoing discussion has presented specific embodiments, persons skilled in the art will recognize that changes may be made in form and detail without departing from the broader spirit and scope of the invention. Accordingly, the specification and drawings are to be regarded in an illustrative rather than a restrictive sense. This detailed description, therefore, is not to be taken in a limiting sense, and the scope of the invention is defined only by the included claims, along with the full range of equivalents to which such claims are entitled.

### REFERENCE SIGNS LIST

1,2,3 In-vehicle device
10 Housing
10a, 10b Air hole
10c Space
11 Duct
11a First wall surface
11b Second wall surface
12 Support member
13 Lower duct segment
20 Coil device
21 Casing
21a Bottom surface
21b Top surface
22 Fin
22a, 22b Void
23 Coil
24 Conductor
31 First fastener
32 Second fastener
41 Heat-receiving block
41a First main surface
41b Second main surface
41c Interconnecting hole
41d Hole wall surface
42 Electronic component
43,44 Heat radiating member

1. A coil device, comprising:
a coil wound around a central axis thereof; and
a casing having a cavity therein to accommodate the coil in the cavity, the casing being made of a casted or injection molded product, wherein
the casing is accommodated in a duct such that at least a part of a bottom surface of the casing abuts on a first wall surface, the duct extending in a direction intersecting a vertical direction inside a housing of an in-vehicle device, the duct defining a space into which air outside the housing flows, the first wall surface being an inner surface of the duct located below in the vertical direction, and
the casing is fixed to the first wall surface and a second wall surface, the second wall surface being an inner surface of the duct located above in the vertical direction.

2. The coil device according to claim 1, wherein the casing is accommodated in the duct such that the bottom surface is in surface contact with the first wall surface.

3. The coil device according to claim 2, wherein the casing is fixed to the first wall surface such that the bottom surface is in surface contact with the first wall surface.

4. The coil device according claim 1, wherein the casing is accommodated in the duct such that at least a part of a top surface of the casing abuts on the second wall surface.

5. to 13. (canceled)

14. The coil device according to claim 2, wherein the casing is accommodated in the duct such that at least a part of a top surface of the casing abuts on the second wall surface.

15. The coil device according to claim 4, wherein the casing is accommodated in the duct such that the top surface is in surface contact with the second wall surface.

16. The coil device according to claim 4, wherein the casing is fixed to the second wall surface such that the top surface is in surface contact with the second wall surface.

17. The coil device according to claim 1, wherein the casing partially protrudes into a space through an interconnecting hole formed in the second wall surface, and is fixed to the duct such that the casing abuts on a hole wall surface being an inner wall of the interconnecting hole, the space being surrounded by an outer surface of the duct and an inner surface of the housing.

18. The coil device according to claim 2, wherein the casing partially protrudes into a space through an interconnecting hole formed in the second wall surface, and is fixed to the duct such that the casing abuts on a hole wall surface being an inner wall of the interconnecting hole, the space being surrounded by an outer surface of the duct and an inner surface of the housing.

19. The coil device according to claim 4, wherein the casing partially protrudes into a space through an interconnecting hole formed in the second wall surface, and is fixed to the duct such that the casing abuts on a hole wall surface being an inner wall of the interconnecting hole, the space being surrounded by an outer surface of the duct and an inner surface of the housing.

20. The coil device according to claim 1, further comprising:
fins provided on a side surface of the casing and accommodated in the duct, the fins having main surfaces extending along a direction of extension of the duct.

21. The coil device according to claim 2, further comprising:
fins provided on a side surface of the casing and accommodated in the duct, the fins having main surfaces extending along a direction of extension of the duct.

22. The coil device according to claim 4, further comprising:
fins provided on a side surface of the casing and accommodated in the duct, the fins having main surfaces extending along a direction of extension of the duct.

23. The coil device according to claim 20, wherein a fin located at a lowermost end in the vertical direction among the fins is fixed to the first wall surface such that the fin is in surface contact with the first wall surface.

24. The coil device according to claim 20, wherein a fin located at an uppermost end in the vertical direction among the fins is fixed to the second wall surface such that the fin is in surface contact with the second wall surface.

25. The coil device according to claim 20, wherein the casing and the fins are integrally formed.

26. An in-vehicle device to be installed in a vehicle, the in-vehicle device comprising:
the coil device according to claim 1;
a housing including a duct therein extending in a direction intersecting a vertical direction, the duct defining a space into which air outside the housing flows to accommodate the coil device in the space;
first fasteners to fix the casing of the coil device to a first wall surface such that at least a part of a bottom surface of the casing abuts on the first wall surface, the first wall surface being an inner surface of the duct located below in the vertical direction; and
second fasteners to fix the casing to a second wall surface, the second wall surface being an inner surface of the duct located above in the vertical direction.

27. The in-vehicle device according to claim 26, further comprising:
a heat-receiving block having a first main surface and a second main surface, the first main surface forming the second wall surface, the second main surface being located opposite to the first main surface and being provided with a heating element; and
a heat radiating member provided on the first main surface inside the duct, the heat radiating member being configured to discharge, to the air that has entered the duct, heat transferred from the heating element via the heat-receiving block.
